(19) United States
(12) Patent Application Publication
(10) Pub. No.: US 2015/0262947 A1
(43) Pub. Date: Sep. 17, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Hironobu SHIBATA, Nonoichi Ishikawa (JP)

(21) Appl. No.: 14/474,017

(22) Filed: Aug. 29, 2014

(30) Foreign Application Priority Data
Mar. 17, 2014 (JP) 2014-053761

(51) Int. Cl. H01L 23/00

(52) U.S. Cl. CPC H01L 24/05; H01L 24/03; H01L 2224/05083; H01L 2224/05155; H01L 2224/05111; H01L 2924/0132; H01L 2924/014

(57) ABSTRACT

According to one embodiment, a semiconductor device includes first layer that includes a first metal element and a second layer that is provided on the first layer and includes the first metal element and a second metal element that is different from the first metal element. The semiconductor device also includes a solder layer that is provided on the second layer such that the second layer is between the first and solder layers. The solder layer includes the second metal element.

### CROSS-REFERENCE TO RELATED APPLICATION

This application is based upon and claims the benefit of priority from Japanese Patent Application No. 2014-053761, filed Mar. 17, 2014, the entire contents of which are incorporated herein by reference.

### FIELD

Embodiments described herein relate generally to a semiconductor device and a method of manufacturing the same.

### BACKGROUND

Typically, a back surface electrode of a semiconductor device is formed of nickel (Ni), and a solder is formed of tin (Sn). When the back surface electrode and the solder are joined to each other, there is a possibility that Ni atoms in the back surface electrode may diffuse into the solder or a possibility that a Ni₃Sn₄ alloy layer may be non-uniformly formed at the junction between the back surface electrode and the solder. In these cases, there is a problem in that an appropriate junction between the back surface electrode and the solder is not achieved resulting in poor device performance.

### DESCRIPTION OF THE DRAWINGS

FIGS. 1A to 1C are cross-sectional views illustrating a method of manufacturing a semiconductor device according to a first embodiment.

FIGS. 2A to 2D are cross-sectional views illustrating a method of manufacturing a semiconductor device according to a comparative example.

FIG. 3 is a cross-sectional view illustrating an example of a structure of the semiconductor device according to the first embodiment.

FIGS. 4A and 4B are plan views illustrating a first example of an electrode structure of the semiconductor device according to the first embodiment.

FIGS. 5A and 5B are plan views illustrating a second example of the electrode structure of the semiconductor device according to the first embodiment.

FIGS. 6A to 6C are cross-sectional views illustrating a method of manufacturing a semiconductor device according to a second embodiment.

### DETAILED DESCRIPTION

An example embodiment of the present disclosure provides a semiconductor device having an appropriate junction between an electrode material and a solder material and a method of manufacturing such a semiconductor device is also disclosed.

A semiconductor device according to a first embodiment comprises a first layer including a first metal element and a second layer on the first layer including the first metal element and a second metal element. The second metal element is different from the first metal element. A solder layer is provided on the second layer such that the second layer is between the first and solder layers. The solder layer includes the second metal element.

Hereinafter, the exemplary embodiments will be described with reference to the accompanying drawings.

### First Embodiment

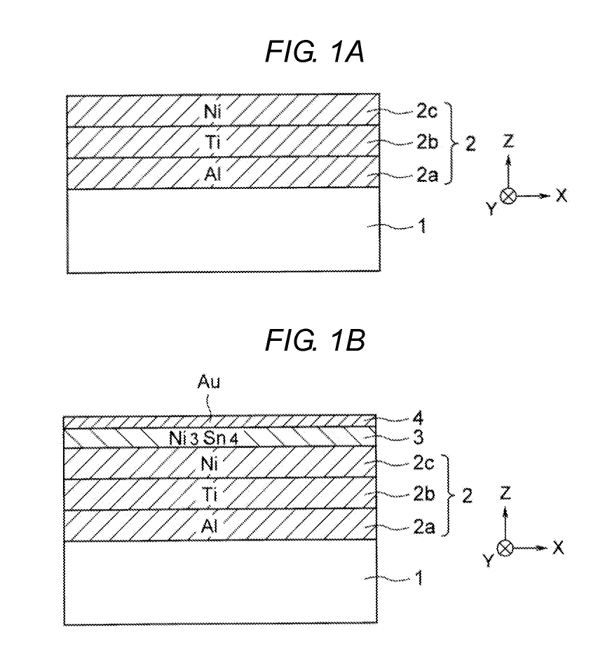

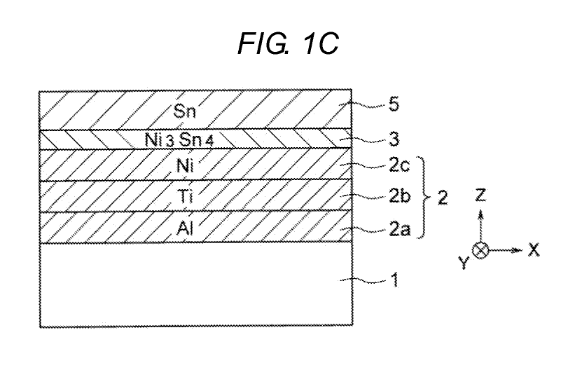

FIGS. 1A to 1C are cross-sectional views illustrating a method of manufacturing a semiconductor device according to a first embodiment. An example of the semiconductor device according to this first embodiment is a power semiconductor device having a front surface electrode and a back surface electrode.

First, as illustrated in FIG. 1A, an electrode layer 2 is formed on a substrate 1. Specifically, a first electrode layer 2a, a second electrode layer 2b, and a third electrode layer 2c are sequentially formed on the substrate 1.

An example of the substrate 1 is a semiconductor substrate such as a silicon substrate. In FIG. 1A, X and Y directions are parallel to the substrate 1 and are perpendicular to each other and a Z direction is perpendicular to the substrate 1 are illustrated. In the exemplary embodiments, a +Z direction is set as an up direction, and a −Z direction is set as a down direction. Thus, for purposes of explanation regarding a positional relationship between the substrate 1 and the electrode layer 2, as depicted in FIG. 1A, the substrate 1 may be referred to as positioned below the electrode layer 2.

For example, the electrode layer 2 is a back surface electrode of the semiconductor device. An example of the first electrode layer 2a is an aluminum (Al) layer. An example of the second electrode layer 2b is a titanium (Ti) layer. An example of the third electrode layer 2c is a nickel (Ni) layer. The third electrode layer 2c is an example of an electrode layer that contains a first metal element. In addition, Ni is an example of the first metal element.

Next, as illustrated in FIG. 1B, a metal layer 3 and a protective layer 4 are sequentially formed on the electrode layer 2.

The metal layer 3 is a layer for joining the electrode layer 2 and a solder layer 5 to each other. The metal layer 3 according to the embodiment is an alloy layer that contains Ni and tin (Sn) as alloy components, specifically, a Ni₃Sn₄ alloy layer in this example embodiment. Sn is an example of a second metal element different from the first metal element. The metal layer 3 may contain other elements in addition to Ni and Sn.

The protective layer 4 is a layer that prevents the metal layer 3 from being oxidized. An example of the protective layer 4 is a gold (Au) layer or a silver (Ag) layer. Au or Ag is an example of a third metal element different from the first and second metal elements. In addition, the protective layer 4 is an example of a layer that contains the third metal element. The protective layer 4 is formed on the electrode layer 2 through the metal layer 3 in any region and is formed with being separated from the electrode layer 2. Accordingly, the protective layer 4 is in non-contact with the electrode layer 2.

Next, as illustrated in FIG. 1C, the solder layer 5 is formed on the metal layer 3 through the protective layer 4 after forming the metal layer 3 and the protective layer 4 on the electrode layer 2. During this process, constituent atoms (Au atoms or Ag atoms) of the protective layer 4 are diffused into the solder layer 5, and the protective layer 4 is eliminated.

An example of the solder layer 5 is a Sn layer. The solder layer 5 is formed on the electrode layer 2 through the metal layer 3 and is formed separated from the electrode layer 2. Accordingly, the solder layer 5 is in non-contact with the electrode layer 2. In the first embodiment, the electrode layer 2 and the solder layer 5 are joined to each other through the metal layer 3.

In this way, a semiconductor chip of the semiconductor device according to the embodiment is manufactured. Next, this semiconductor chip is arranged on, for example, a lead frame or an insulating substrate. In this case, the solder layer 5 is joined to, for example, an interconnect for connecting the semiconductor chip and the lead frame or an interconnect formed on the insulating substrate.

### (1) First Embodiment and Comparative Example Thereof

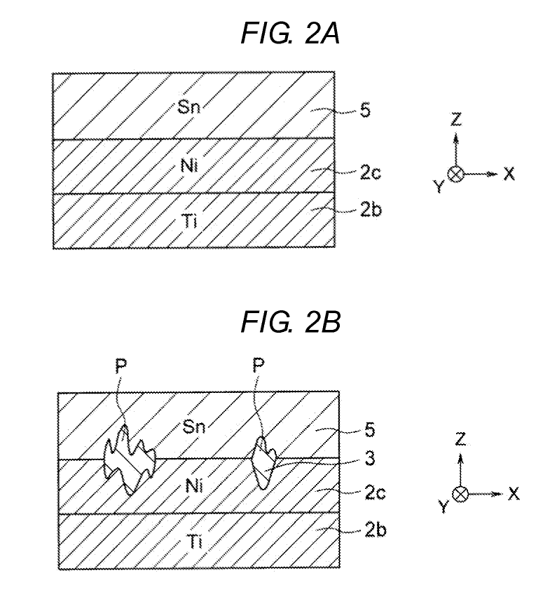

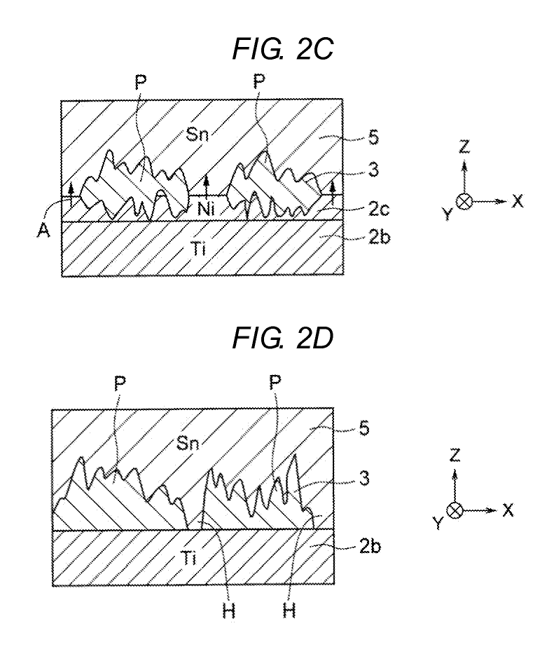

FIGS. 2A to 2D are cross-sectional views illustrating a method of manufacturing a semiconductor device according to a comparative example.

FIG. 2A is a cross-sectional view corresponding to FIG. 1A. However, in FIG. 2A, the substrate 1 and the first electrode layer 2a are not specifically illustrated. The solder layer 5 of FIG. 2A is directly formed on the third electrode layer 2c.

In this case, Ni atoms in the third electrode layer 2c react with Sn atoms in the solder layer 5 such that the metal layer 3 is formed on an interface between the third electrode layer 2c and the solder layer 5 (FIG. 2B). This metal layer 3 is a Ni₃Sn₄ alloy layer. Symbol P represents plural Ni₃Sn₄ crystal grains forming the metal layer 3.

As illustrated in FIG. 2C, the Ni₃Sn₄ crystal grains P are further grown even after the state of FIG. 2B. At this time, since there are gaps between the Ni₃Sn₄ crystal grains P, as indicated by arrow A, most of Ni atoms in the third electrode layer 2c are diffused into the solder layer 5 through the gaps.

As a result, there is a possibility that the third electrode layer 2c may be eliminated (FIG. 2D). Further, finally, gaps H remain between the Ni₃Sn₄ crystal grains P, and there is a possibility that the metal layer 3 may be non-uniformly formed (FIG. 2D). In FIG. 2D, the electrode layer 2 and the solder layer 5 are in contact with each other at the gaps H. In this case, there is a problem in that an appropriate junction between the electrode layer 2 and the solder layer 5 is not achieved.

On the other hand, in the first embodiment, the metal layer 3 is formed on the electrode layer 2 in advance before forming the solder layer 5 on the electrode layer 2. Accordingly, according to the first embodiment, unlike the above-described comparative example, a metal layer 3 having no gaps H may be formed, and the erosion of the third electrode layer 2c by diffusion may be avoided. In addition, according to the first embodiment, the metal layer 3 having good uniformity in thickness may be formed.

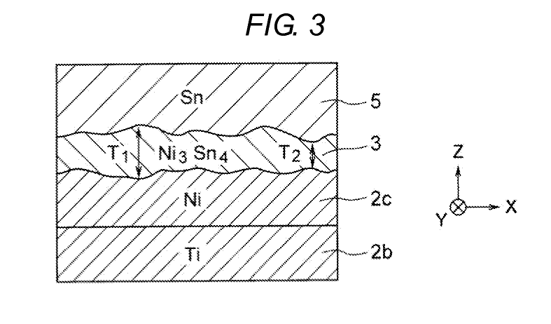

FIG. 3 is a cross-sectional view illustrating an example of a structure of the semiconductor device according to the first embodiment.

FIG. 3 is a cross-sectional view corresponding to FIG. 1C, and an example of a shape of the metal layer 3 of FIG. 1C will be described in detail. Symbol T₁ represents a maximum value of the thickness of the metal layer 3. Symbol T₂ represents a minimum value of the thickness of the metal layer 3.

The uniformity in the thickness of the metal layer 3 according to the embodiment is good, and a difference between the maximum value T₁ and the minimum value T₂ is small. The thickness of the metal layer 3 is substantially constant immediately after the formation of the metal layer 3 but varies due to the growth of a Ni₃Sn₄ alloy and the diffusion of Ni atoms after the formation of the solder layer 5. However, even after such growth and diffusion, the uniformity in the thickness of the metal layer 3 according to the first embodiment is better than that of the metal layer 3 according to the comparative example. According to the first embodiment, the maximum value T₁ of the thickness of the metal layer 3 may be set to be substantially two times or less the minimum value T₂ of the thickness of the metal layer 3.

In addition, unlike the above-described comparative example, the metal layer 3 of FIG. 3 has no gaps H. Accordingly, the solder layer 5 of FIG. 3 is formed on the electrode layer 2 through the metal layer 3 in any region and is formed with being separated from the electrode layer 2.

### (2) Example of Electrode Structure of First Embodiment

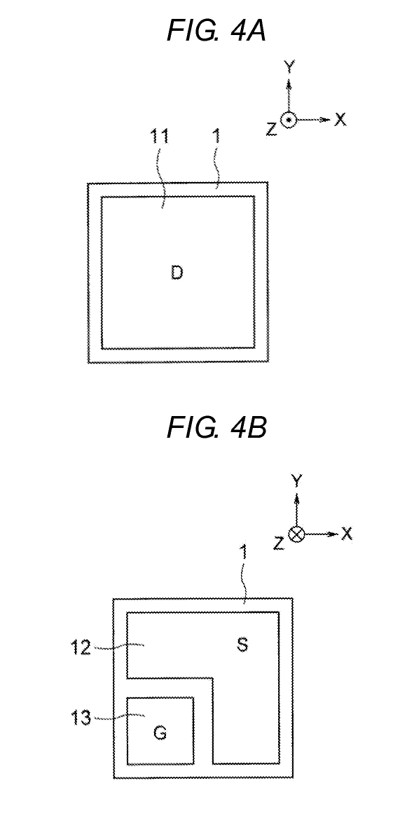

FIGS. 4A and 4B are plan views illustrating a first example of an electrode structure of the semiconductor device according to the first embodiment.

FIG. 4A illustrates the semiconductor device when seen from the +Z direction. FIG. 4B illustrates the semiconductor device when seen from the −Z direction. FIG. 4A illustrates a back surface of the substrate 1, and FIG. 4B illustrates a front surface of the substrate 1. The direction along the Z-axis may be referred to as the stacking direction.

This semiconductor device includes a drain electrode 11 that is formed on the back surface of the substrate 1, a source electrode 12 that is formed on the front surface of the substrate 1, and a gate electrode 13 that is formed on the front surface of the substrate 1. Accordingly, the drain electrode 11 is a back surface electrode, and the source electrode 12 and the gate electrode 13 are front surface electrodes. The semiconductor chip of the semiconductor device is accommodated, for example, a package including a drain terminal, a source terminal, and a gate terminal having a rod shape.

The drain electrode 11 of FIG. 4A is formed by the electrode layer 2. The metal layer 3 and the solder layer 5 according to the embodiment are formed on the drain electrode 11 of FIG. 4A.

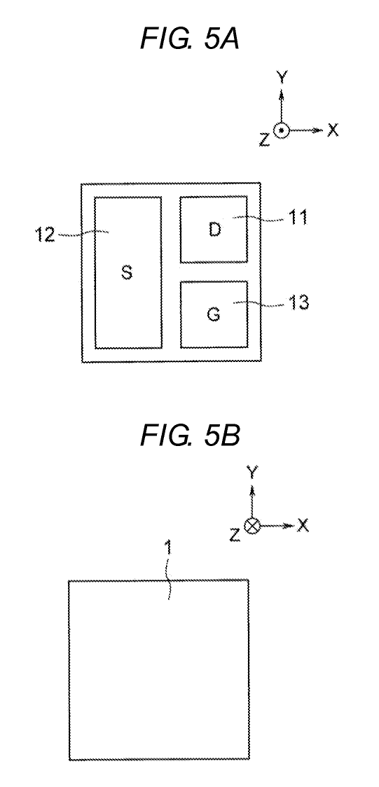

FIGS. 5A and 5B are plan views illustrating a second example of the electrode structure of the semiconductor device according to the first embodiment.

FIG. 5A illustrates the semiconductor device when seen from the +Z direction. FIG. 5B illustrates the semiconductor device when seen from the −Z direction. FIG. 5A illustrates one surface of the substrate 1, and FIG. 5B illustrates the other surface of the substrate 1.

This semiconductor device includes the drain electrode 11, the source electrode 12, and the gate electrode 13 which are formed on the same surface of the substrate 1. An example of a transistor including the electrodes 11, 12, and 13 is a high electron mobility transistor (HEMT). A semiconductor chip of this semiconductor device is accommodated, for example, a “chip size package” (CSP) type package (also referred to as a “chip-scale package”).

The drain electrode 11, the source electrode 12, and the gate electrode 13 of FIG. 5A are formed by the electrode layer 2 according to the embodiment. The metal layer 3 and the solder layer 5 according to the embodiment are formed on the drain electrode 11, the source electrode 12, and the gate electrode 13 of FIG. 5A.

As described above, in the first embodiment, the metal layer 3, that contains a constituent element of the electrode layer 2 and a constituent element of the solder layer 5, is formed on the electrode layer 2 in advance before forming the solder layer 5 on the electrode layer 2. Accordingly, an appropriate junction between the electrode layer 2 and the solder layer 5 may be achieved by the metal layer 3.

When the semiconductor device according to the first embodiment is manufactured, the following first and second manufacturing modes are considered. In the first manufacturing mode, the same processes as those of FIGS. 1A to 1C are performed by the same manufacturer. In the second manufacturing mode, the processes of FIGS. 1A and 1B are performed by a first manufacturer, and the process of FIG. 1C is performed by a second manufacturer. When the second manufacturing mode is adopted, the semiconductor device in the state of FIG. 1B is transported from the first manufacturer to the second manufacturer. Therefore, the function of the protective layer 4 preventing the metal layer 3 from being oxidized is highly useful compared to when the first manufacturing mode is adopted.

### Second Embodiment

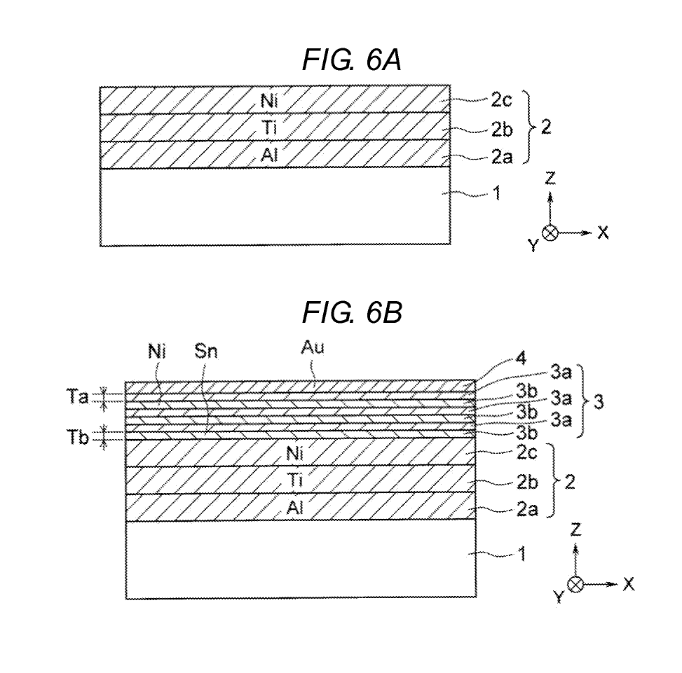

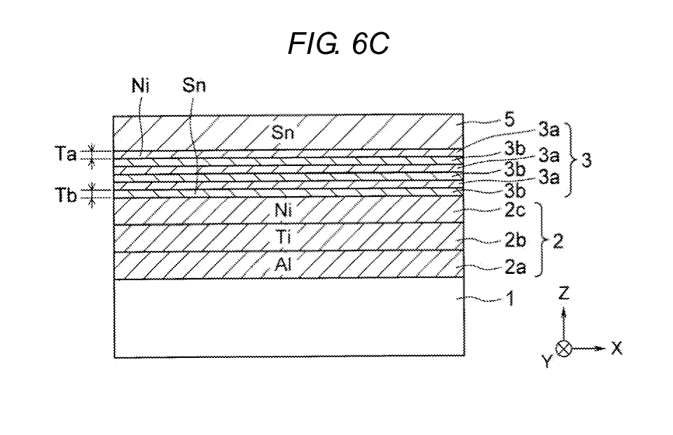

FIGS. 6A to 6C are cross-sectional views illustrating a method of manufacturing a semiconductor device according to a second embodiment.

First, as illustrated in FIG. 6A, the electrode layer 2 including the first, second, and third electrode layers 2a, 2b, and 2c is formed on the substrate 1. Examples of the first, second, and third electrode layers 2a, 2b, and 2c are an Al layer, a Ti layer, and a Ni layer, respectively.

Next, as illustrated in FIG. 6B, the metal layer 3 and the protective layer 4 are sequentially formed on the electrode layer 2.

The metal layer 3 according to the second embodiment is a laminated film that alternately includes one or more first metal layers 3a and one or more second metal layers 3b. The metal layer 3 according to the second embodiment is formed by alternately forming the first metal layers 3a and the second metal layers 3b on the electrode layer 2. An example of the first metal layer 3a is a Ni layer, and an example of the second metal layer 3b is a Sn layer. In addition, an example of the protective layer 4 is an Au layer or an Ag layer.

Symbol Ta represents the thickness of each of the first metal layers 3a. When the number of the first metal layers 3a is Na, the total thickness of the first metal layers 3a of the semiconductor device is Na×Ta. Symbol Tb represents the thickness of each of the second metal layers 3b. When the number of the second metal layers 3b is Nb, the total thickness of the second metal layers 3b of the semiconductor device is Nb×Tb.

In the second embodiment, a ratio of the total thickness (Na×Ta) of the first metal layers 3a to the total thickness (Nb×Tb) of the second metal layers 3b is set to substantially 1:3. An example of the total thickness Na×Ta is 3 nm×10 nm. An example of the total thickness Nb×Tb is 3 nm×30 nm.

The atomic weight of Ni is 58.7 g/mol, and the density of Ni is 8.9 g/cm³. On the other hand, the atomic weight of Sn is 118.7 g/mol, and the density of Sn is 7.4 g/cm³ (β tin) or 5.8 g/cm³ (α tin). Tin at standard temperature and pressure is β tin. Accordingly, when the ratio of the total thickness Na×Ta to the total thickness Nb×Tb is set to 1:3, a ratio of the total molar number of Ni atoms in the first metal layer (nickel layer) 3a to the total molar number of Sn atoms in the second metal layer (β tin layer) 3b is 3:4. This ratio is suitable for forming a Ni₃Sn₄ alloy.

Accordingly, in the second embodiment, it is preferable that the total thickness Nb×Tb be set to be substantially three times the total thickness Na×Ta. In some embodiments the total thickness Nb×Tb is approximately 2.5 times to 3.5 times the total thickness Na×Ta. In this case, the ratio of the total molar number of Ni atoms in the first metal layer 3a to the total molar number of Sn atoms in the second metal layer 3b is approximately 3:3.3 to 3:4.7.

Next, as illustrated in FIG. 6C, the solder layer 5 is formed on the metal layer 3 through the protective layer 4 after forming the metal layer 3 and the protective layer 4 on the electrode layer 2. During this process, constituent atoms of the protective layer 4 are diffused into the solder layer 5, and the protective layer 4 is eliminated. An example of the solder layer 5 is a Sn layer.

After the process of FIG. 6B, Ni atoms in the first metal layer 3a react with Sn atoms in the second metal layer 3b such that most or the entire portion of the metal layer 3 is changed into a Ni₃Sn₄ alloy layer. The electrode layer 2 and the solder layer 5 are joined to each other through this Ni₃Sn₄ alloy layer.

In this way, a semiconductor chip of the semiconductor device according to the second embodiment is manufactured. Next, this semiconductor chip is arranged on, for example, a lead frame or an insulating substrate.

Similarly to the case of the first embodiment, the metal layer 3 is formed on the electrode layer 2 in advance before forming the solder layer 5 on the electrode layer 2. Accordingly, unlike the above-described comparative example, the metal layer 3 having no gaps H may be formed, and the erosion of the third electrode layer 2c may be avoided. In addition, according to the second embodiment, the metal layer 3 having good uniformity in thickness may be formed.

As described above, in the second embodiment, the metal layer 3, that contains a constituent element of the electrode layer 2 and a constituent element of the solder layer 5, is formed on the electrode layer 2 in advance before forming the solder layer 5 on the electrode layer 2. Accordingly, similarly to the case of the first embodiment, an appropriate junction between the electrode layer 2 and the solder layer 5 may be achieved by the metal layer 3.

The thicknesses Ta of the first metal layers 3a according to the second embodiment may be different from one another. Likewise, the thicknesses Tb of the second metal layers 3b according to the second embodiment may be different from one another.

In addition, the first metal layer 3a according to the second embodiment may further contain other elements in addition to Ni. Likewise, the second metal layer 3b according to the second embodiment may further contain other elements in addition to Sn.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first layer including a first metal element;
a second layer on the first layer and including the first metal element and a second metal element that is different from the first metal element; and
a solder layer on the second metal layer such that second layer is between the first and solder layers, and including the second metal element.

2. The semiconductor device according to claim 1, wherein a maximum thickness of the second layer in a stacking direction of the first and second layers is two times or less a minimum thickness of the second layer in the stacking direction.

3. The semiconductor device according to claim 1, wherein the second layer is an alloy having the first metal element and the second metal element as alloy components.

4. The semiconductor device according to claim 1, wherein the first metal element is nickel and the second metal element is tin.

5. The semiconductor device according to claim 1, wherein the second layer includes one or more first metal layers including the first metal element and one or more second metal layers including the second metal element.

6. The semiconductor device according to claim 5, wherein a combined thickness of the one or more second metal layers is between 2.5 and 3.5 times a combined total thickness of the one or more first metal layers.

7. The semiconductor device according to claim 5, wherein a combined thickness of the one or more second metal layers is approximately three times a combined thickness of the one or more first metal layers.

8. The semiconductor device according to claim 1, further comprising:
a third layer between the second layer and the solder layer, the third metal layer comprising a third metal element different from the first and second metal elements.

9. A semiconductor device, comprising:
a first layer that includes a first metal element;
a second layer on the first layer and including a plurality of first metal layers and a plurality of second metal layers, the first and second layers alternating in a stacking direction, the first metal layers including the first metal element and the second metal layers including a second metal element different from the first metal element; and
a third layer on the second metal layer such that the second metal layer is between the first and third layers, the third layer including a third metal element different from the first and second metal elements.

10. The semiconductor device according to claim 9, further comprising:
a solder layer including the second metal element, the second layer being between the first and solder layers in the stacking direction.

11. The semiconductor device according to claim 9, wherein a maximum value of a thickness of the second layer in the stacking direction is two times or less a minimum value of a thickness of the second layer in the stacking direction.

12. The semiconductor device according to claim 9, wherein a combined thickness of the plurality of second metal layers is between 2.5 and 3.5 times a combined total thickness of the plurality of first layers.

13. The semiconductor device according to claim 9, wherein a combined thickness of the plurality of second layers is approximately three times a combined thickness of the plurality of first layers.

14. The semiconductor device according to claim 9, wherein the first metal element is nickel and the second metal element is tin.

15. A method of manufacturing a semiconductor device, comprising:
forming a first layer that includes a first metal element;
forming a second layer that includes the first metal element and a second metal element that is different from the first metal element on the first layer; and
forming a solder layer that includes the second metal element on the second metal layer such that the second metal layer is between the first and solder layers.

16. The method according to claim 15, wherein the second layer is an alloy layer including the first metal element and the second metal element as alloy components.

17. The method according to claim 15, wherein the second layer includes a plurality of first metal layers including the first metal element and a plurality of second metal layers including the second metal element.

18. The method according to claim 17, wherein the plurality of first metal layers alternate with the second metal layers in a stacking direction.

19. The method according to claim 15, further comprising:
forming a third layer including a third metal element different from the first and second metal elements on the second layer before forming the solder layer on the second metal layer.

20. The method according to claim 15, wherein the first metal element is nickel and the second metal element is tin.
